(19) United States
(12) Patent Application Publication
(10) Pub. No.: US 2025/0391077 A1
(43) Pub. Date: Dec. 25, 2025

(54) COMPUTER PROGRAM, INFORMATION PROCESSING METHOD, AND INFORMATION PROCESSING DEVICE

(71) Applicant: Tokyo Electron Limited, Tokyo (JP)

(72) Inventors: Tsuyoshi MIZUUCHI, Sapporo-shi (JP); Takahiko KATO, Miyagi (JP)

(73) Assignee: Tokyo Electron Limited, Tokyo (JP)

(21) Appl. No.: 19/315,910

(22) Filed: Sep. 2, 2025

Related U.S. Application Data
(63) Continuation of application No. PCT/JP2024/006915, filed on Feb. 27, 2024.

(30) Foreign Application Priority Data
Mar. 6, 2023 (JP) 2023-033778

(51) Int. Cl. G06T 11/60; G06T 11/00

(52) U.S. Cl. CPC G06T 11/60; G06T 11/001

(57) ABSTRACT

The present disclosure provides a non-transitory computer-readable storage medium, an information processing method, and an information processing device that clarify a relationship among a plurality of processing steps included in a plurality of recipes. The non-transitory computer-readable storage medium having computer-executable instructions stored thereon, which when executed by a processor, cause the processor to perform a method including acquiring a plurality of recipe data related to a plurality of recipes, each of the plurality of recipes including processing steps executed sequentially for processing a substrate, the plurality of the recipe data including contents of each processing step and a processing result of each processing step, and arranging graphic images representing the processing steps included in the plurality of the recipes based on the plurality of the recipe data in an order in which the processing steps are executed, and displaying the graphic images in a tree shape such that the processing steps having common contents across the recipes are grouped into one group and the processing steps having different contents are branched.

### CROSS-REFERENCE TO RELATED APPLICATIONS

This application is a bypass continuation application of international application No. PCT/JP2024/006915 having an international filing date of Feb. 27, 2024, and designating the United States, the international application being based upon and claiming the benefit of priority from Japanese Patent Application No. 2023-033778, filed on Mar. 6, 2023, the entire contents of each are incorporated herein by reference.

### TECHNICAL FIELD

The present disclosure relates to a computer program, an information processing method, and an information processing device.

### BACKGROUND

Substrate processing which involves etching, film formation, or the like on a substrate such as a semiconductor wafer is executed according to a recipe that defines processing contents. The recipe is a combination of a plurality of processing steps in a set order, and processing contents of each processing step are set. A shape simulation is executed using a computer to predict a shape of a substrate obtained by executing substrate processing according to a processing step. An experiment is also executed in which the substrate processing according to the processing step is actually executed. An appropriate recipe for obtaining a desired substrate shape is searched for with reference to a processing result obtained through the substrate processing executed according to a processing step, including a result of the shape simulation or a result of the experiment. PTL 1 discloses an example of a technique for searching for an appropriate recipe.

### CITATION LIST

### Patent Documents

Patent Document 1: WO2019/155928

### SUMMARY

The shape simulation or the experiment is executed for various recipes or various processing steps, and processing results are recorded in a database. In order to use the processing results, it is necessary to clarify a relationship among various processing steps. For example, in order to compare two processing results, it is necessary to clarify transition of processing steps until respective processing results are obtained.

The present disclosure provides a computer program, an information processing method, and an information processing device that clarify a relationship among a plurality of processing steps included in a plurality of recipes.

The computer program causes a computer to acquire a plurality of recipe data related to a plurality of recipes each including processing steps executed sequentially for processing a substrate, the plurality of the recipe data including contents of each processing step and a processing result of each processing step, and arrange graphic images representing the processing steps included in a plurality of the recipes based on the plurality of the recipe data in an order in which the processing steps are executed, and display the graphic images in a tree shape such that the processing steps having common contents across the plurality of the recipes are grouped into one group and the processing steps having different contents are branched.

According to the present disclosure, a computer program, an information processing method, and an information processing device that clarify a relationship among a plurality of processing steps included in a plurality of recipes can be provided.

### BRIEF DESCRIPTION OF DRAWINGS

FIG. 1 is a conceptual diagram illustrating a configuration example of an information processing system according to the present embodiment;

FIG. 2 is a block diagram illustrating an internal configuration example of an information processing device;

FIG. 3 is a conceptual diagram illustrating an example of contents of recipe data;

FIG. 4 is a flowchart illustrating an example of a processing procedure for displaying a relationship among processing steps, which is executed by the information processing device;

FIG. 5 is a schematic diagram illustrating an example of graphic images representing a plurality of processing steps in a grouped manner;

FIG. 6 is a schematic diagram illustrating an example of a plurality of graphic images displayed in a branched manner;

FIG. 7 is a schematic diagram illustrating an example of a graphic image for which a color is adjusted according to a Loss value of an experiment and a Loss value of a simulation;

FIG. 8 is a schematic diagram illustrating an example of a plurality of processing results displayed in association with graphic images;

FIG. 9 is a schematic diagram illustrating an example of a plurality of graphic images displayed in a tree shape;

FIG. 10 is a flowchart illustrating an example of a processing procedure for changing display of a graphic image and a processing result, which is executed by the information processing device;

FIG. 11 is a schematic diagram illustrating a first example in which a plurality of processing results related to a plurality of specified processing steps are displayed;

FIG. 12 is a schematic diagram illustrating a second example in which a plurality of processing results related to a plurality of specified processing steps are displayed; and

FIG. 13 is a schematic diagram illustrating an example of a display change in response to creation of a new processing step.

### DETAILED DESCRIPTION

Hereinafter, the disclosure will be specifically described with reference to the drawings illustrating an embodiment thereof.

A process for producing a substrate such as a semiconductor wafer, a glass substrate, or a flat panel substrate includes a process of performing processing such as etching or film formation on a substrate. Hereinafter, the processing performed on the substrate will be referred to as substrate processing, and an apparatus for executing the substrate processing will be referred to as a processing apparatus. For example, the processing device includes a process chamber, and executes the substrate processing, such as etching and film formation, on a substrate disposed in the process chamber. The processing device processes the substrate according to a predetermined recipe in which processing contents are set. The recipe is information for defining contents of the substrate processing, and includes a plurality of processing steps whose order is determined. Each processing step is a smallest unit of a time series processing procedure for the substrate. In each processing step, contents of processing to be performed on the substrate are determined. There may be a plurality of recipes having different processing steps. In the present embodiment, information processing is executed to visualize a relationship among a plurality of processing steps included in a plurality of recipes.

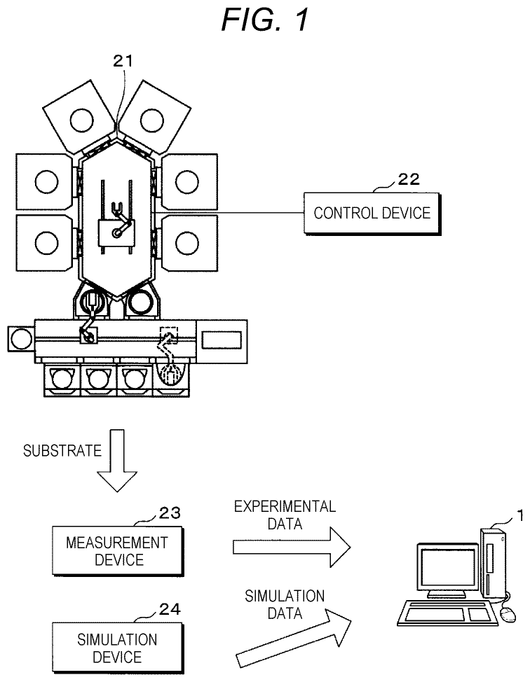

FIG. 1 is a conceptual diagram illustrating a configuration example of an information processing system according to the present embodiment. The information processing system includes a processing device 21 that executes substrate processing, a control device 22 that controls the processing device 21, a measurement device 23 that measures a shape of a substrate, a simulation device 24, and an information processing device 1. The processing device 21 includes, for example, a process chamber, and executes substrate processing such as etching or film formation. The control device 22 adjusts a processing condition for the substrate processing executed by processing device 21. The processing condition defines contents of the substrate processing executed according to a processing step. The control device 22 adjusts a processing condition according to the contents of the processing step, and the processing device 21 executes the substrate processing according to the processing step by executing the substrate processing under the adjusted processing condition. For example, the processing device 21 executes the substrate processing according to any one processing step included in any one recipe, thereby executing an experiment in the processing step.

The measurement device 23 measures a shape of the substrate. The measurement device 23 is, for example, a scanning electron microscope or a transmission electron microscope. For example, the substrate is cut, and a cross-sectional shape of the substrate is measured by the measurement device 23. For example, the shape of the substrate is measured after the substrate processing according to a certain processing step is executed. After an experiment in which the processing device 21 executes the substrate processing according to a processing step, the measurement device 23 measures the shape of the substrate, thereby obtaining an experimental result of the processing step. The experimental result includes the shape of the substrate obtained through the experiment. The shape of the substrate may be measured by the measurement device 23 before the processing device 21 executes the substrate processing according to the processing step.

The simulation device 24 executes a shape simulation. The simulation device 24 is implemented by a computer, and executes the shape simulation using a simulation model to be described later. The simulation device 24 executes a simulation for a processing step by executing a shape simulation for predicting a shape of the substrate obtained through the substrate processing executed according to any processing step included in any recipe. Information indicating contents of the processing step is input into the simulation device 24, and the simulation device 24 executes the shape simulation based on the input information. For example, the information indicating contents of the processing step is input from the control device 22 to the simulation device 24. The simulation device 24 generates a simulation result of the processing step by executing a simulation for the processing step. The simulation result includes a predicted shape obtained by predicting a shape of the substrate obtained by the substrate processing executed according to the processing step.

The information processing device 1 executes an information processing method. The information processing device 1 stores a plurality of recipe data related to a plurality of recipes. The recipe data includes contents of each processing step and a processing result of each processing step. The processing result of the processing step includes an experimental result of the processing step or a simulation result of the processing step. The experimental result of the processing step is input from the measurement device 23 to the information processing device 1. The simulation result of the processing step is input from the simulation device 24 to the information processing device 1. Contents of the processing step may be input from the control device 22 to the information processing device 1. Based on the recipe data, the information processing device 1 executes information processing to visualize a relationship among processing steps included in a plurality of recipes.

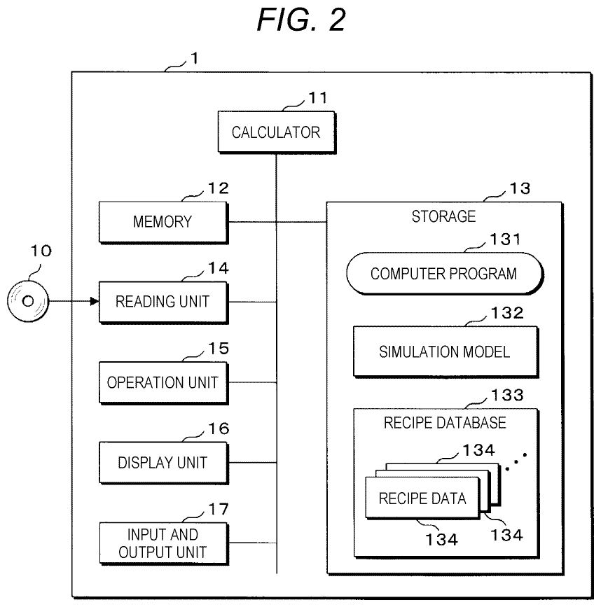

FIG. 2 is a block diagram illustrating an internal configuration example of the information processing device 1. The information processing device 1 is implemented using a computer such as a personal computer or a server device. The information processing device 1 includes a calculator 11, a memory 12, a storage 13, a reading unit 14, an operation unit 15, a display unit 16, and an input and output unit 17. The calculator 11 is implemented using, for example, a central processing unit (CPU), a graphics processing unit (GPU), or a multi-core CPU. The calculator 11 may also be implemented using a quantum computer. The memory 12 stores temporary data generated along with calculation. The memory 12 is, for example, a random access memory (RAM). The storage 13 is non-volatile, and is, for example, a hard disk or a non-volatile semiconductor memory. The reading unit 14 reads information from a recording medium 10 such as an optical disk or a portable memory.

The operation unit 15 receives an input of information such as text by receiving an operation from a user. The operation unit 15 is, for example, a keyboard, a pointing device, or a touch panel. The display unit 16 displays an image. The display unit 16 is, for example, a liquid crystal display or an electroluminescent display (EL display). The operation unit 15 and the display unit 16 may be integrated. The input and output unit 17 inputs and outputs data. The input and output unit 17 is, for example, an input and output interface or a communication unit. The input and output unit 17 receives an input of data.

The calculator 11 causes the reading unit 14 to read a computer program 131 recorded in the recording medium 10, and causes the storage 13 to store the read computer program 131. The calculator 11 executes processing for implementing functions of the information processing device 1 according to the computer program 131. The computer program 131 may be stored in advance in the storage 13 or may be downloaded from outside the information processing device 1. In this case, the information processing device 1 does not need to be provided with the reading unit 14.

The computer program 131 may be loaded to be executed on a single computer or on a plurality of computers disposed at one site or distributed across a plurality of sites and interconnected by a communication network. That is, the information processing device 1 may be implemented by a plurality of computers, and the computer program 131 may be executed on the plurality of computers connected via the communication network. The information processing device 1 may be implemented using a cloud server.

The information processing device 1 includes a simulation model 132 that performs a shape simulation for predicting a substrate shape obtained by substrate processing. In the shape simulation, the simulation model 132 executes a simulation of executing substrate processing on a substrate having any shape according to any one processing step. At this time, the simulation model 132 calculates a predicted shape obtained by simulating a shape of the substrate obtained through the substrate processing executed according to a processing step. For example, the simulation model 132 simulates the substrate processing based on data indicating a shape of a substrate before the substrate processing and contents of a processing step, and calculates the predicted shape. The simulation model 132 includes a computer program for the shape simulation. The computer program for executing a shape simulation is stored in the storage 13 and included in, for example, the computer program 131. The simulation model 132 may be a trained model that outputs the predicted shape when a shape of the substrate and contents of the processing step are input. In such an aspect, the simulation model 132 is implemented by the calculator 11 executing information processing according to the computer program 131. For example, the simulation model 132 is implemented using a neural network.

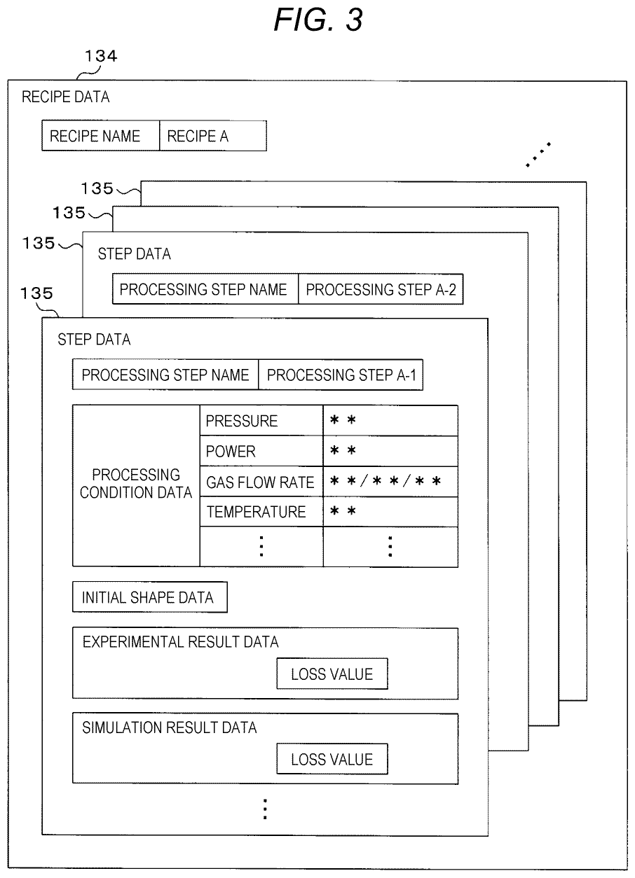

The storage 13 stores a recipe database 133 in which recipe data is recorded. A plurality of recipe data 134 representing a plurality of recipes are recorded in the recipe database 133. One piece of the recipe data 134 is recorded for one recipe. FIG. 3 is a conceptual diagram illustrating an example of contents of recipe data. The recipe data includes a recipe name. FIG. 3 illustrates an example in which the recipe name is recipe A. The recipe data includes step data related to a plurality of processing steps included in a recipe.

The step data includes various kinds of data related to processing steps. The step data includes a processing step name. FIG. 3 illustrates an example in which the processing step name is processing step A-1 or processing step A-2. The step data includes data representing contents of a processing step. The step data includes processing condition data representing a processing condition for the substrate processing as the data representing contents of a processing step. A pressure in the process chamber, power supplied to the process chamber during the substrate processing, flow rates of a plurality of types of gases supplied to the process chamber, and a temperature in the process chamber are recorded in the processing condition data. The processing condition data may define a processing condition other than pressure, power, gas flow rate, and temperature.

The step data includes initial shape data representing an initial shape that is a shape of the substrate immediately before the substrate processing is executed according to a processing step. The initial shape data represents, for example, the initial shape obtained when an experiment or a shape simulation is executed. The initial shape data may be an image. The initial shape data may be data representing a plurality of initial shapes.

The step data includes experimental result data representing an experimental result of the substrate processing executed according to a processing step. In an experiment, the substrate processing is executed under a processing condition indicated by the processing condition data. The experimental result data includes data representing a shape of the substrate obtained through an experiment. The data representing the shape of the substrate may include an image. The experimental result data may include data representing results of an experiment executed multiple times, or may include the number of times of execution of an experiment. The experimental result data includes a Loss value of the experiment, which is an output value of a loss function for calculating a deviation between a target shape of the substrate to be obtained through the substrate processing executed according to a processing step and a shape of the substrate obtained through an experiment. As the Loss value of the experiment increases, the difference between an experimental result and the target shape increases.

The step data stores simulation result data representing a result obtained by simulating the substrate processing executed according to a processing step. The simulation is a shape simulation in which the substrate processing executed under a processing condition indicated by the processing condition data is simulated to calculate a predicted shape. The simulation result data includes data representing a predicted shape of the substrate calculated by the shape simulation. The simulation result data may include data representing results of a shape simulation executed a plurality of times, or may include the number of times of execution of the shape simulation. The simulation result data includes a Loss value of a simulation, which is an output value of a loss function that calculates a deviation between the target shape and the predicted shape calculated by the shape simulation. As the Loss value of the simulation increases, the difference between the result of the shape simulation and the target shape increases.

An experimental result represented by experimental result data and a simulation result represented by simulation result data correspond to a processing result of a processing step related to the step data. The step data may include both the experimental result data and the simulation result data, or may include only one of the experimental result data and the simulation result data. The recipe data or the step data includes the order in which the substrate processing is executed according to each processing step included in a recipe. The recipe data or the step data may further include other information.

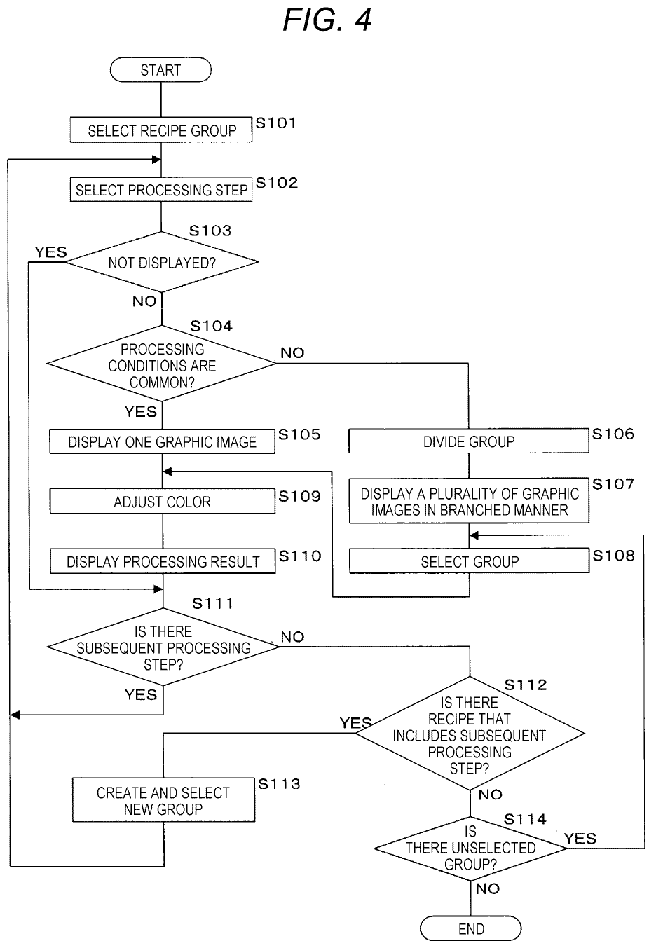

The information processing executed by the information processing device 1 will be described. The information processing device 1 executes processing to visualize a relationship among processing steps included in a plurality of recipes. FIG. 4 is a flowchart illustrating an example of a processing procedure for displaying a relationship among processing steps, which is executed by the information processing device 1. Hereinafter, the step of the information processing executed by the information processing device 1 will be abbreviated as S. The information processing device 1 executes the following processing by the calculator 11 executing the information processing according to the computer program 131.

The information processing device 1 selects a group of recipes (S101). In S101, the calculator 11 selects a group including a plurality of recipes for which the recipe data 134 is recorded in the recipe database 133. For example, at the initial, the calculator 11 selects a group that includes all recipes. The calculator 11 reads the recipe data 134 of recipes included in the selected group from the recipe database 133, thereby acquiring a plurality of recipe data. Next, the information processing device 1 selects a processing step included in each recipe (S102). In S102, the calculator 11 selects one processing step from each recipe included in the selected group. At this time, the calculator 11 selects a processing step having the earliest order among processing steps, which is not selected for display in each step. For example, when S102 is executed first, a first processing step included in each recipe is selected.

Next, the information processing device 1 determines whether the selected processing step is not displayed (S103). A predetermined condition for not displaying the processing step is determined in advance. For example, the predetermined condition may be a condition in which a process time, which is a time for which the substrate processing is executed according to a processing step, is equal to or less than a threshold value, or a processing step name is a predetermined name. For example, the predetermined condition may be a processing step other than a main processing step having a large influence on the shape of the substrate. The processing step other than the main processing step includes a predetermined processing step automatically included in a recipe or a typical processing step included in many recipes. The predetermined condition for not displaying a processing step is stored in advance in the storage 13.

In S103, the calculator 11 compares contents of step data 135 corresponding to the selected processing step with the predetermined condition. When the contents of the step data 135 fall under the predetermined condition, the calculator 11 determines that the selected processing step is not displayed, and when the contents of the step data 135 do not fall under the predetermined condition, the calculator 11 determines that the selected processing step is displayed. When the selected processing step is not displayed (S103: YES), the calculator 11 proceeds the processing to S111 to be described later.

When the selected processing step is displayed (S103: NO), the information processing device 1 determines whether processing conditions of a plurality of the selected processing steps are common (S104). In S104, the calculator 11 determines whether the processing conditions represented by the processing condition data included in the step data 135 corresponding to the selected processing steps are common. For example, when a difference in values of the respective processing conditions between the processing steps falls within a predetermined range, the calculator 11 determines that the processing conditions are common. When the number of processing conditions under which the difference in the values falls within the predetermined range exceeds a predetermined number, the calculator 11 may determine that the processing conditions are common. When the difference in values of predetermined specific processing conditions falls within the predetermined range, the calculator 11 may determine that the processing conditions are common.

When the processing conditions of the plurality of selected processing steps are common (S104: YES), the information processing device 1 displays one graphic image representing the processing steps (S105). In S105, the calculator 11 creates one graphic image representing a plurality of processing steps having common processing condition in a grouped manner, and displays the graphic image on the display unit 16.

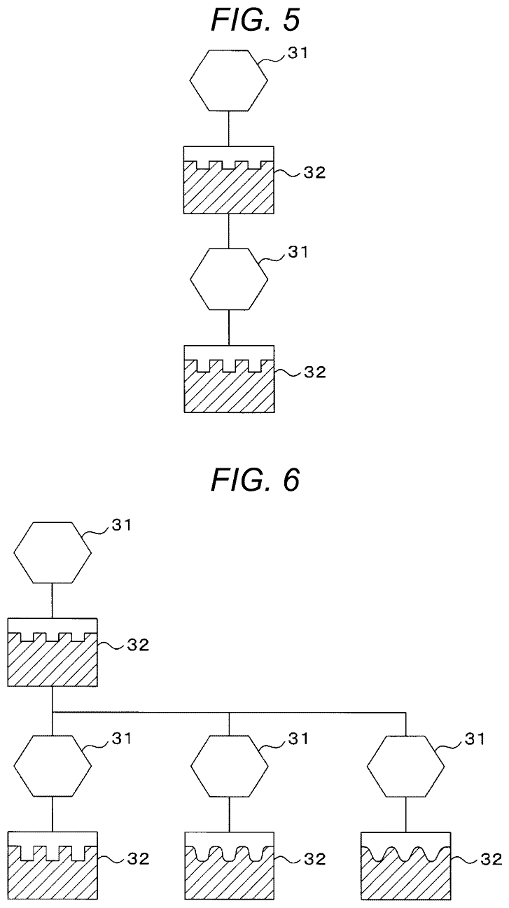

FIG. 5 is a schematic diagram illustrating an example of graphic images 31 representing a plurality of processing steps in a grouped manner. In FIG. 5, the graphic image 31 is illustrated as a hexagonal figure. The graphic image 31 is, for example, an icon. The graphic image 31 represents a plurality of processing steps having common processing conditions across a plurality of selected recipes in a grouped manner. When the graphic images 31 representing a plurality of processing steps executed before the plurality of selected processing steps are already displayed, the calculator 11 displays the graphic images 31 side by side in the order in which the processing steps are executed. For example, the plurality of graphic images 31 are displayed to be aligned from top to bottom in the order in which the processing steps are executed. The calculator 11 displays the graphic images 31 in a manner of connecting the graphic image 31 to the graphic image 31 representing a preceding processing step with a line. The calculator 11 may display a processing step name accompanying the graphic image 31. In this manner, the information processing device 1 displays the plurality of graphic images 31 in a tree shape.

When only a single recipe is included in the selected group, the information processing device 1 determines in S104 that the processing conditions of the processing steps are common. In S105, the information processing device 1 displays one graphic image representing the single recipe included in the group.

When the plurality of selected processing steps include processing steps in which the processing conditions are not common (S104: NO), the calculator 11 divides the selected recipe group into a plurality of groups (S106). In S106, the calculator 11 divides the selected recipe group into a plurality of groups each representing, in a grouped manner, recipes including processing steps having common processing conditions. Some of the division groups may include only a single recipe. When a group includes a plurality of recipes, a plurality of selected processing steps included in the plurality of recipes have common processing conditions.

Next, the information processing device 1 displays, in a branched manner, a plurality of the graphic images 31 representing a plurality of processing steps included in recipes included in the plurality of groups (S107). In S107, the calculator 11 creates the graphic images 31 representing the selected processing steps included in the recipes included in each group, for each division groups, and displays the graphic images 31 on the display unit 16. When only a single recipe is included in a group, the graphic image 31 illustrates a single processing step. When a plurality of recipes are included in a group, the graphic image 31 represents a plurality of processing steps in a grouped manner.

FIG. 6 is a schematic diagram illustrating an example of a plurality of graphic images 31 displayed in a branched manner. The calculator 11 displays the plurality of graphic images 31 in parallel. When the graphic images 31 representing a plurality of processing steps executed before the plurality of selected processing steps are already displayed, the calculator 11 displays the graphic images 31 side by side in the order in which the processing steps are executed. For example, the plurality of graphic images 31 are aligned from top to bottom in the order in which processing steps are executed, and the plurality of graphic images 31 corresponding to a plurality of division groups are arranged in a lateral direction. The calculator 11 connects each of the plurality of graphic images 31 to the graphic image 31 representing a preceding processing step with a line. The calculator 11 may display a processing step name along with each of the graphic images 31. In this manner, the information processing device 1 displays the plurality of graphic images 31 in a manner of branching from the graphic image 31 representing the preceding processing step, and displays the plurality of graphic images 31 in a tree shape as a whole.

The information processing device 1 selects a group (S108). In S108, the calculator 11 selects one group from a plurality of groups obtained by division in S106. The selected group includes one or more recipes. The calculator 11 selects a processing step illustrated by the graphic image 31 included in a recipe included in the selected group and displayed in S107.

After S105 or S108 is completed, the information processing device 1 adjusts a color of the graphic image 31 (S109). In S109, the calculator 11 adjusts the color of the graphic image 31 according to contents of the selected processing step. For example, the color of the graphic image 31 is adjusted according to a value of any processing condition recorded in the processing condition data. For example, a relationship between a value of a processing condition and a color change is determined in advance such that as the value of the processing condition such as a pressure increases, the color is closer to blue, and as the value decreases, the color is closer to red. For example, a relationship between a value of a processing condition and the shade of color is determined in advance such that as the value of the processing condition increases, the color becomes darker, and as the value decreases, the color becomes lighter. For example, a table defining the relationship between a value of a processing condition and a color in such a manner is stored in advance in the storage 13.

For example, based on the relationship between the color and the value of the processing condition recorded in the table, the calculator 11 determines the color of the graphic image 31 according to the value of the processing condition recorded in the processing condition data included in the step data corresponding to the processing step represented by the graphic image 31. The calculator 11 sets the color of the graphic image 31 to a determined color. A user can easily know a processing condition in a processing step according to the color of the graphic image 31.

In S109, the calculator 11 may adjust the color of the graphic image 31 according to a processing result of the selected processing step. For example, the experimental result data included in the step data includes a measurement result obtained by the measurement device 23 measuring a shape of a substrate obtained through an experiment, the number of experiments, or an evaluation value for an experimental result. For example, the simulation result data includes a value of a parameter used in a shape simulation, the number of times the shape simulation is executed, or an evaluation value for a simulation result. For example, a table defining a relationship between a value of a such a processing result and a color is stored in advance in the storage 13. For example, based on the relationship between the value of the processing result and the color recorded in the table, the calculator 11 determines the color of the graphic image 31 according to the value of the processing result included in the experimental result data or the simulation result data. The calculator 11 sets the color of the graphic image 31 to a determined color. A user can know a processing result of a processing step in a simplified manner according to the color of the graphic image 31.

In S109, the calculator 11 may adjust the color of the graphic image 31 based on a Loss value in an experiment and a Loss value in a simulation. For example, a table defining a relationship between a Loss value and a color is stored in advance in the storage 13. Based on the relationship between the Loss value and the color recorded in the table, the calculator 11 determines the color of the graphic image 31 according to Loss values included in the experimental result data and the simulation result data. The calculator 11 sets the color of the graphic image 31 to a determined color.

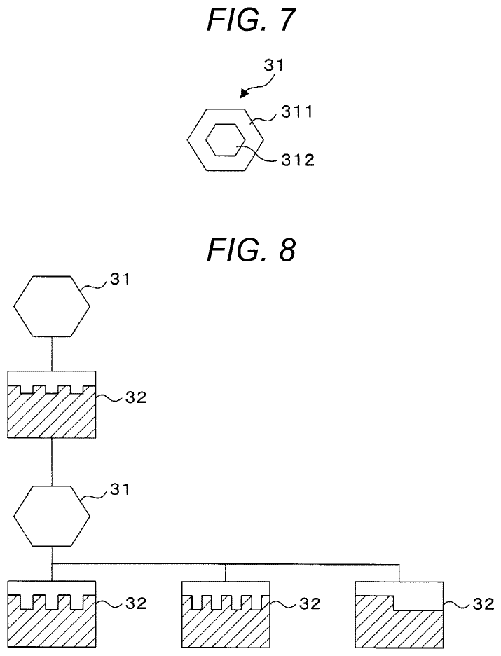

FIG. 7 is a schematic diagram illustrating an example of the graphic image 31 for which a color is adjusted according to a Loss value of an experiment and a Loss value of a simulation. The graphic image 31 is divided into two regions of a first region 311 and a second region 312. The calculator 11 adjusts a color of the first region 311 according to a Loss value in an experiment included in the experimental result data. Further, the calculator 11 adjusts a color of the second region 312 according to a Loss value in a simulation included in the simulation result data.

Since the color of the graphic image 31 is adjusted according to the Loss value, a user who sees the graphic image 31 can recognize an approximate value of the Loss value based on the color of the graphic image 31. As the Loss value in the experiment or the simulation increases, a difference between an experimental result or a simulation result and a target shape increases. A user can confirm accuracy of the experiment and the shape simulation according to the color of the graphic image 31. The information processing device 1 may adjust the color of the graphic image 31 according to only one of the Loss value in the experiment or the Loss value in the simulation.

Which information of contents of processing steps and processing results of the processing steps is used to adjust the color of the graphic image 31 may be set in advance or selected by a user. For example, the user operates the operation unit 15 to specify information, and the calculator 11 adjusts the color of the graphic image 31 according to the specified information. For example, the user selects as to whether the color of the graphic image 31 is adjusted according to which value of a processing condition recorded in the processing condition data.

A relationship between the color of the graphic image 31 and the contents of the processing steps or the processing results of the processing steps may have a plurality of patterns. For example, a table recording a plurality of patterns is stored in the storage 13, the user selects a pattern by operating the operation unit 15, and the calculator 11 adjusts the color of the graphic image 31 according to the selected pattern. A user can confirm the contents of the processing steps or the processing results of the processing steps in a simplified manner by using an easy-to-see color. When the graphic image 31 represents a plurality of processing steps in a grouped manner, the color of the graphic image 31 may be adjusted according to information related to any one processing step, or the color of the graphic image 31 may be adjusted according to information obtained by averaging information related to the plurality of processing steps.

Next, the information processing device 1 displays a processing result of the processing step represented by the graphic image 31 (S110). In S110, the calculator 11 creates an image representing an experimental result or a simulation result as a processing result based on experimental result data or simulation result data included in the step data, and displays the created image on the display unit 16. At this time, the calculator 11 displays, in association with the graphic image 31, a processing result of a processing step represented by the graphic image 31. For example, the calculator 11 displays a processing result below the graphic image 31.

FIGS. 5 and 6 illustrate examples in which the processing results 32 are displayed together with the graphic images 31. As illustrated in FIGS. 5 and 6, the calculator 11 displays the processing result 32 below the graphic image 31, and displays the graphic image 31 representing a processing step to be executed subsequently below the processing result 32. The calculator 11 connects the graphic image 31 and the processing result 32 with a line. In this manner, each processing result 32 is displayed between the plurality of graphic images 31 arranged in the order in which the processing steps are executed, and the graphic images 31 and the processing results 32 are displayed in a tree shape. The processing result 32 may be displayed at a position other than the position below the graphic image 31, as long as the processing result 32 is displayed at a position associated with the graphic image 31. For example, the calculator 11 may integrally display the graphic image 31 and the processing result 32 by disposing the processing result 32 at a position overlapping the graphic image 31.

An image representing an experimental result or a simulation result is displayed as the processing result 32. For example, a cross-sectional view of a substrate after an experiment is displayed as the processing result 32 based on data indicating a shape of the substrate obtained through the experiment, the data being included in the experimental result data. An image of the substrate included in the experimental result data may be displayed as the processing result 32. For example, a cross-sectional view of a predicted shape is displayed as the processing result 32 based on data indicating the predicted shape included in the simulation result data. The processing result 32 may be displayed in a form other than an image. For example, a numerical value indicating an experimental result or a simulation result such as a size of a specific portion of the substrate may be displayed as the processing result 32. An image and other kinds of information may be displayed together as the processing result 32. For example, an image indicating an experimental result or a simulation result, and a numerical value indicating a condition of an experiment or a shape simulation may be displayed.

A plurality of the processing results 32 may be displayed in association with the graphic image 31. For example, an image indicating an experimental result and an image representing a simulation result are displayed. For example, when the graphic image 31 represents a plurality of processing steps in a grouped manner, the processing results 32 of the respective processing steps are displayed. For example, the processing results 32 at a plurality of locations on the substrate are displayed. FIG. 8 is a schematic diagram illustrating an example of a plurality of the processing results 32 displayed in association with the graphic images 31. A cross-sectional view of a plurality of locations of the substrate after an experiment is illustrated as a plurality of the processing results 32. The plurality of processing results 32 are displayed side by side in relation to one graphic image 31. In the example illustrated in FIG. 8, the calculator 11 displays, side by side in a horizontal direction, the plurality of processing results 32 related to one graphic image 31 in a manner of connecting the plurality of processing results 32 to the graphic image 31 with lines.

All the processing results 32 related to the processing steps illustrated by the graphic image 31 may be displayed, or only some of the processing results 32 may be displayed. Only one of an image representing an experimental result or an image representing a simulation result may be displayed as the processing result 32. The processing result 32 to be displayed may be selected from a plurality of processing results that can be displayed by a user operating the operation unit 15. When contents of the experimental result data and the simulation result data included in the step data are insufficient, a processing result may not be displayed. In this case, for example, the calculator 11 displays a blank image at a position where the processing result 32 is to be displayed in $110.

The information processing device 1 may further execute processing for displaying an initial shape of the substrate, separately from the processing result 32. At this time, the calculator 11 displays an image representing the initial shape of the substrate on the display unit 16 based on initial shape data included in the step data. The calculator 11 displays the initial shape of the substrate at a position corresponding to a position before the processing step. For example, the initial shape of the substrate is displayed above the graphic image 31. For example, the calculator 11 displays the initial shape of the substrate before executing the substrate processing at a position above the graphic image 31 representing the first processing step.

Next, the information processing device 1 determines whether there is a processing step to be executed subsequent to the selected processing step (S111). In S111, the calculator 11 determines whether there is any subsequent processing step in all recipes included in the selected group. The calculator 11 makes the determination based on whether the step data 135 corresponding to the subsequent processing step is included in the recipe data 134 representing a recipe included in the selected group. When there is a subsequent processing step in all recipes included in the selected group (S111: YES), the information processing device 1 returns the processing to S102. In S102, the calculator 11 selects the subsequent processing step in each recipe included in the selected group.

When there is no subsequent processing step in any recipe included in the selected group (S111: NO), the information processing device 1 determines whether there is a recipe that includes the subsequent processing step (S112). In S112, the calculator 11 determines whether the subsequent processing step is included in any recipe included in the selected group.

When there is a recipe that includes the subsequent processing step (S112: YES), the information processing device 1 creates a new group including the recipe that includes the subsequent processing step, and selects the created group (S113). In S113, the calculator 11 extracts a recipe that includes the subsequent processing step from the recipes included in the selected group, creates a new group that includes only the extracted recipe, and selects the created new group. Next, the information processing device 1 returns the processing to S102.

In S102, the calculator 11 selects the subsequent processing step included in the recipe included in the new group. When the graphic images 31 corresponding to the new group are displayed in subsequent processing, the information processing device 1 displays the graphic images 31 in a branched manner.

When there is no recipe that includes the subsequent processing step (S112: NO), the information processing device 1 determines whether there is an unselected group (S114). In S114, the calculator 11 determines whether there is any unselected group among the plurality of groups obtained by division in S106. When there is an unselected group (S114: YES), the information processing device 1 returns the processing to S108. In S108, the calculator 11 selects one unselected group from the plurality of groups obtained by division in S106. When there is no unselected group (S114: NO), the information processing device 1 ends the processing of displaying a relationship among processing steps.

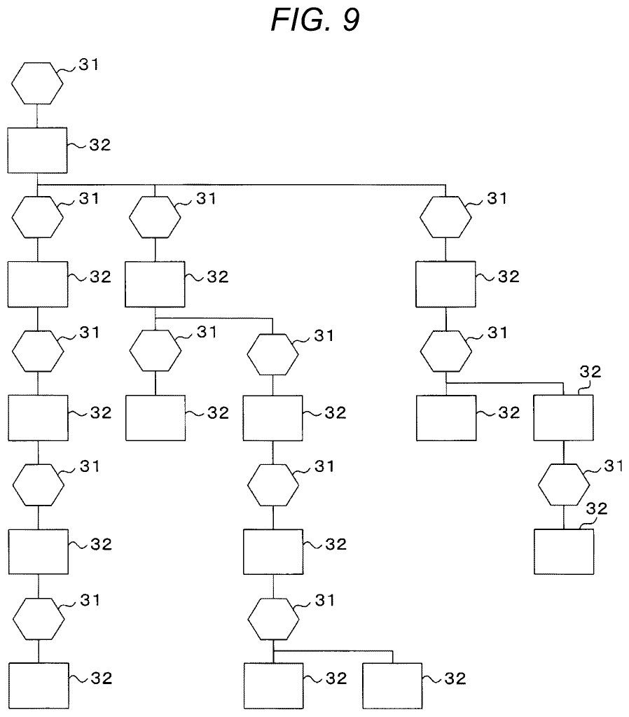

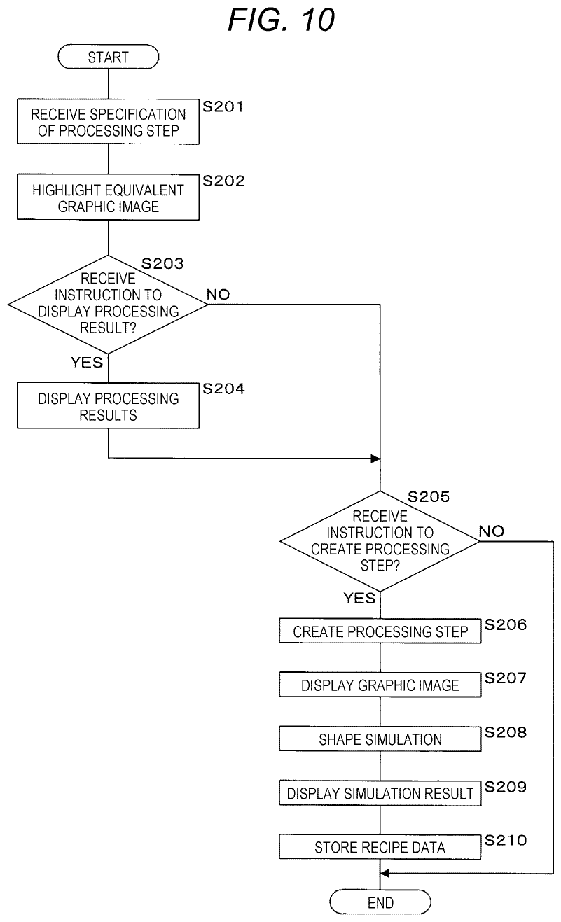

Through the processing in S101 to S114, the plurality of graphic images 31 representing a plurality of processing steps are displayed in a tree shape. FIG. 9 is a schematic diagram illustrating an example of the plurality of graphic images 31 displayed in a tree shape. In FIG. 9, the processing result 32 is represented by a rectangle, and contents of the processing result 32 are omitted. For example, as illustrated in FIG. 9, the plurality of graphic images 31 are displayed in a tree shape for five recipes. Since the plurality of graphic images 31 are displayed side by side in the order in which the processing steps are executed, a user who sees the plurality of graphic images 31 can easily recognize the order in which the processing steps are executed. The user can confirm transition of the processing steps by sequentially following the graphic images 31 arranged in the order in which the processing steps are executed.

A plurality of processing steps having common contents across a plurality of recipes are represented by one graphic image 31. Therefore, the display for illustrating contents of a plurality of recipes is not complicated, and visibility of contents of each recipe is improved. The user can easily confirm processing steps included in a recipe that have common contents to processing steps included in other recipes among processing steps included in each recipe. In this manner, a relationship among processing steps, that is, contents of which processing step are common among recipes, becomes apparent.

A plurality of processing steps having different contents are represented by a plurality of the graphic images 31. The plurality of graphic images 31 representing a plurality of processing steps having different contents are displayed while being branched from one graphic image 31 representing a plurality of processing steps having common contents. A user can easily confirm a plurality of processing steps having different contents among processing steps included in each recipe. In this manner, a relationship among processing steps, that is, contents of which processing step are common among recipes, becomes apparent.

The processing results 32 of processing steps are displayed between the plurality of graphic images 31 arranged in the order in which the processing steps are executed, and the processing result 32 includes an experimental result or a simulation result. When the processing results 32 are displayed together with the graphic images 31 displayed in a tree shape, the processing results 32 are also displayed in a tree shape. When the processing results 32 are displayed together with the graphic images 31 arranged in the order in which the processing steps are executed, a user can easily recognize the transition of the processing results 32 obtained in the order in which the processing steps are executed. In particular, since an experimental result is often obtained through a destructive inspection, transition of experimental results cannot be actually obtained. However, when the experimental results are displayed as the processing results 32, a user can confirm the transition of the experimental results. A relationship among processing steps becomes clear, and thus a relationship among the processing results 32 of the processing steps becomes clear.

The information processing device 1 may display the graphic image 31 for a part of the recipe data 134 among the recipe data 134 that records recipes in the recipe database 133. For example, the information processing device 1 displays the graphic image 31 for the recipe data 134 that matches a predetermined display condition. For example, the information processing device 1 receives a display condition by a user operating the operation unit 15, and displays the graphic image 31 for the recipe data 134 that matches the received display condition. The display condition include, for example, a shape of a circuit formed on the substrate, a position at which the substrate is subject to substrate processing from which a processing result is obtained, or contents of the substrate processing. The recipe data 134 may be specified in advance, or the recipe data 134 may be specified by a user operating the operation unit 15.

The information processing device 1 can execute information processing for changing the display of the graphic images 31 and the processing results 32. FIG. 10 is a flowchart illustrating an example of a processing procedure for changing the display of the graphic images 31 and the processing results 32, which is executed by the information processing device 1.

The information processing device 1 receives specification of a processing step (S201). In S201, a user operates the operation unit 15 to specify one graphic image 31 from the displayed graphic images 31. For example, the graphic image 31 is specified by placing a cursor 33 on the graphic image 31 on a display surface of the display unit 16. The calculator 11 receives the specification of a processing step indicated by the specified graphic image 31.

The information processing device 1 highlights the graphic image 31 representing a processing step equivalent to the specified processing step (S202). In S202, the calculator 11 searches for a processing step equivalent to the specified processing step, based on a plurality of pieces of the recipe data 134 stored in the recipe database 133. The calculator 11 searches for and specifies the processing step equivalent to the specified processing step such that a predetermined condition such as the same name or the common processing condition is satisfied. The calculator 11 highlights the graphic image 31 representing the processing step specified through the search. For example, the calculator 11 highlights the graphic image 31 by methods such as changing a color of the graphic image 31, bordering the graphic image 31, or flashing the graphic image 31.

In S202, the information processing device 1 may highlight a plurality of the graphic images 31 representing a combination equivalent to a combination of consecutive processing steps including the specified processing step. Based on a plurality of the recipe data 134 stored in the recipe database 133, the calculator 11 searches for and specifies a combination equivalent to a combination of consecutive processing steps that include the specified processing step. The calculator 11 highlights the plurality of graphic images 31 representing the combination of the plurality of processing steps specified through the search. A user can easily confirm a processing step equivalent to the processing steps specified from processing steps included in each recipe. In this manner, a relationship among processing steps becomes clear as to where in the other recipes, a processing step equivalent to the specified processing step or a combination equivalent to the combination of consecutive processing steps that includes the specified processing step are included.

The information processing device 1 waits for reception of an instruction to display the processing result 32 related to the specified processing step (S203). In S203, the calculator 11 receives an instruction to display the processing result 32 by a user operating the operation unit 15. When the instruction to display the processing result 32 is received (S203: YES), the information processing device 1 displays a plurality of processing results related to the specified processing step (S204).

In S204, the calculator 11 creates an image representing an experimental result or a simulation result as a processing result, based on the experimental result data or the simulation result data included in the step data related to the specified processing step, and displays the created image on the display unit 16. When the graphic image 31 represents a plurality of processing steps, a plurality of processing steps are specified, and the calculator 11 displays a plurality of processing results related to the specified plurality of processing steps.

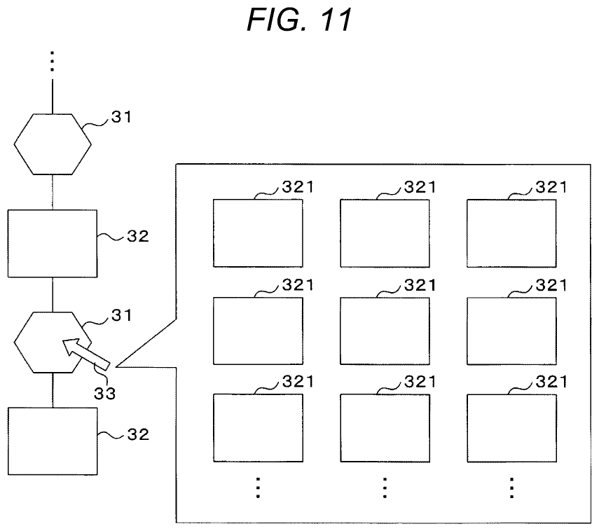

FIG. 11 is a schematic diagram illustrating a first example in which a plurality of processing results related to a plurality of specified processing steps are displayed. In FIG. 11, a processing result is represented by a rectangle, and contents of the processing result is omitted. A plurality of processing steps are specified by placing the cursor 33 on the graphic image 31 representing a plurality of processing steps. Apart from the displayed processing result 32, a plurality of processing results 321 related to a plurality of specified processing steps are displayed. In relation to the plurality of specified processing steps, the calculator 11 displays a plurality of processing results related to a plurality of specified processing steps, based on the experimental result data or the simulation result data included in a plurality of pieces of step data across a plurality of recipe data. For example, all the processing results 321 related to the plurality of specified processing steps are displayed.

A user can confirm the plurality of processing results 321 related to the plurality of specified processing steps. For example, the user can confirm all the plurality of processing results related to the plurality of specified processing steps across a plurality of recipes. When the user operates the operation unit 15, the calculator 11 may receive the specification of any one of the processing results 321, and replace the specified processing result 321 with the processing result 32 displayed along with the graphic image 31.

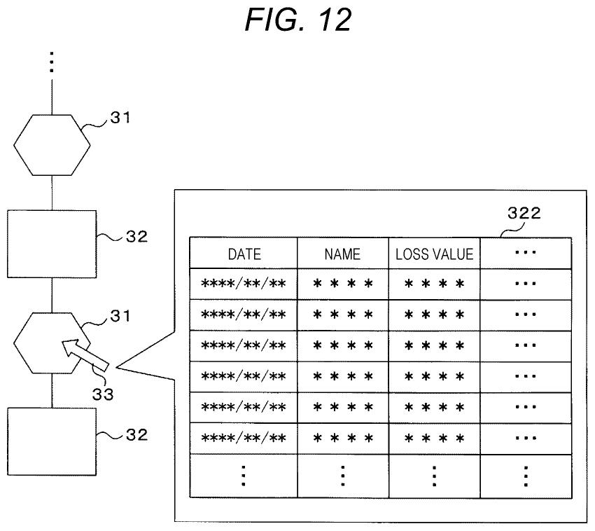

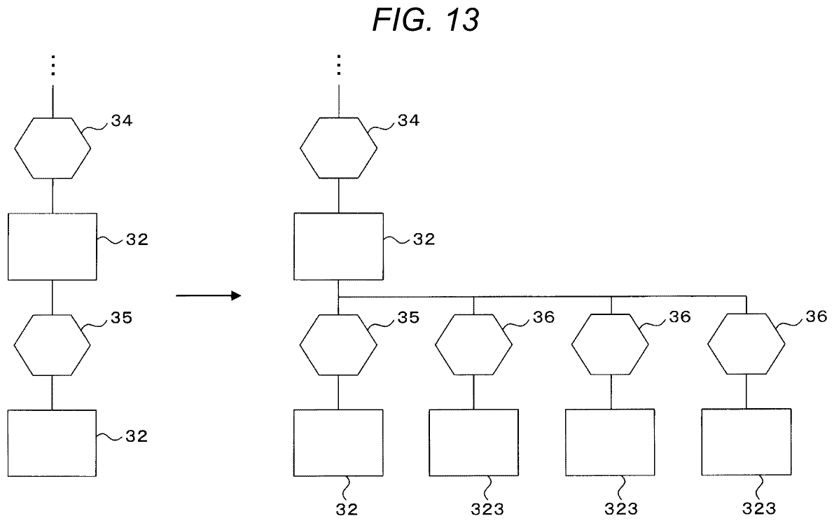

FIG. 12 is a schematic diagram illustrating a second example in which a plurality of processing results related to a plurality of specified processing steps are displayed. In the second example, the calculator 11 displays a list 322 of a plurality of processing results related to the plurality of specified processing steps, based on the experimental result data or the simulation result data included in the plurality of pieces of step data. In the list 322, contents of each processing result are written in characters. In the example illustrated in FIG. 12, a date on which an experiment or a shape simulation has been executed, a name of the experiment or the shape simulation, and a Loss value included in the experimental result data or the simulation result data are displayed. A name of a processing step or a recipe may be displayed.

A user can also confirm the plurality of processing results 321 related to the plurality of specified processing steps in the second example. By displaying the plurality of processing results 321 in a list format, the user can easily confirm a large number of processing results 321. When the user operates the operation unit 15, the calculator 11 may receive specification of any one of the processing results listed in the list 322 and display an image of the specified processing result on the display unit 16. When the user operates the operation unit 15, the calculator 11 may receive an instruction to switch the display, and switch between the display of the plurality of processing results 321 as illustrated in FIG. 11 and the display of the list 322 of processing results as illustrated in FIG. 12.

When the instruction to display the processing result 32 is not received (S203: NO) or after S204 is completed, the information processing device 1 waits for reception of an instruction to create a new processing step (S205). In S205, the calculator 11 receives an instruction to create a new processing step to be executed after the specified processing step when the user operates the operation unit 15.

When the instruction to create a new processing step is received (S205: YES), the information processing device 1 creates a new processing step (S206). In S206, for example, the user operates the operation unit 15 to input a processing condition for a new processing step, and the calculator 11 creates the new processing step by creating step data that includes processing condition data representing the input processing condition. The calculator 11 may determine a processing condition for a new processing step and create the new processing step by changing the processing condition of the specified processing step. Alternatively, the calculator 11 may determine a processing condition for a new processing step and create the new processing step by changing the processing condition of the processing step set in the recipe data 134 to be executed subsequent to the specified processing step. The calculator 11 may create a plurality of processing steps with different processing conditions.

The information processing device 1 displays the graphic image 31 representing the new processing step (S207). In S207, the calculator 11 creates the graphic image 31 representing the new processing step, and displays the graphic image 31 on the display unit 16. The calculator 11 displays the graphic image 31 representing the new processing step in a manner of branching from the graphic image 31 representing the specified processing step. When a plurality of processing steps are created in S206, the calculator 11 displays a plurality of the graphic images 31.

Next, the information processing device 1 executes a shape simulation according to the new processing step (S208). In S208, the calculator 11 uses the simulation model 132 to execute a shape simulation for calculating a predicted shape obtained through substrate processing executed according to the new processing step. When a plurality of processing steps are created in S206, the calculator 11 executes a shape simulation for each processing step. S208 may be executed using the simulation device 24. For example, data necessary for the shape simulation may be transmitted from the information processing device 1 to the simulation device 24, the shape simulation may be executed by the simulation device 24, and a simulation result may be transmitted from the simulation device 24 to the information processing device 1.

Next, the information processing device 1 displays the simulation result (S209). In S209, the calculator 11 creates an image representing the simulation result based on a result of the shape simulation, and displays the created image on the display unit 16. When a plurality of processing steps are created in S206, the calculator 11 displays a simulation result for each processing step. For example, the calculator 11 displays a cross-sectional view of a predicted shape as a simulation result.

FIG. 13 is a schematic diagram illustrating an example of a display change in response to creation of a new processing step. FIG. 13 illustrates display before a new processing step is created, and display after the new processing step is created. It is assumed that a graphic image 34, the processing result 32 of a processing step represented by the graphic image 34, a graphic image 35 representing a processing step subsequent to the processing step represented by the graphic image 34, and the processing result 32 of the processing step represented by the graphic image 35 are displayed. The processing step represented by the graphic image 34 is specified, and a new processing step to be executed subsequent to the specified processing step is created.

As illustrated in FIG. 13, the display changes such that a graphic image 36 representing the new processing step and a simulation result 323 are displayed. In FIG. 13, the processing result 32 and the simulation result 323 are each illustrated by a rectangle, and contents of the processing result 32 and the simulation result 323 are omitted.

The graphic image 36 is displayed in a manner of branching from the graphic image 34. FIG. 13 illustrates an example in which a plurality of processing steps are created and a plurality of the graphic images 36 are displayed. The graphic image 35 and the graphic image 36 are displayed in parallel. For example, the graphic image 35 and the graphic image 36 are displayed in parallel in a lateral direction. The simulation result 323 is displayed in association with the graphic image 36. A user can confirm the simulation result 323 of a processing step having different contents from the processing step represented by the graphic image 35. For example, when a processing result of the processing step represented by the graphic image 35 is unsatisfactory, the user can search for a processing step in which a better processing result can be obtained by checking the simulation result 323.

The information processing device 1 stores the new recipe data 134 including the step data 135 related to the new processing step (S210). In S210, the calculator 11 creates the recipe data 134 including the step data 135 related to the new processing step, and stores the created recipe data 134 in the recipe database 133, thereby storing the recipe data 134 in the storage 13.

The calculator 11 causes the step data 135 to include simulation result data representing a result of the shape simulation executed in S208. The storage of the new recipe data 134 enriches variations in processing steps and increases recipes.

When a plurality of processing steps are created in S206, the calculator 11 selects any one of the processing steps, and records the recipe data 134 including the step data 135 related to the selected processing step in the recipe database 133. For example, the calculator 11 receives specification of any one of a plurality of new processing steps, and selects the specified processing step when a user operates the operation unit 15. For example, the user confirms a plurality of the simulation results 323 and specifies processing steps for obtaining the appropriate simulation results 323. For example, only a processing step for obtaining the more appropriate simulation result 323 than that in the related art is specified, and a new recipe in which a more appropriate processing result than that in the related art may be obtained is created.

The calculator 11 may not select any one processing step. For example, the calculator 11 receives an instruction to not select and does not select any one processing step when the user operates the operation unit 15. In this case, the processing in S210 will be omitted by the information processing device 1.

After S210 is completed, the information processing device 1 ends the processing of changing the display of the graphic image 31 and the processing result 32. The information processing device 1 executes the information processing in S201 to S210 as appropriate. For example, each time the user operates the operation unit 15 to specify the graphic image 31, the information processing device 1 executes the information processing in S201 to S210.

As described in detail above, the information processing device 1 displays the graphic images 31 representing processing steps included in a plurality of recipes in the present embodiment. The graphic images 31 are arranged in the order in which the processing steps are executed, and are displayed in a tree shape such that a plurality of processing steps having common contents across a plurality of recipes are grouped into one group, and a plurality of processing steps having different contents are branched. A relationship among processing steps included in the recipes is visualized, so that a user can clearly recognize the relationship among processing steps. Further, the information processing device 1 displays the processing results 32 of processing steps in association with the graphic images 31. The user can also clearly recognize a relationship among processing results of the processing steps. It becomes clear through what background each processing result can be obtained, and it becomes easier to search for an appropriate recipe by adjusting processing steps in the intermediate of a recipe so as to obtain a desired processing result.

The invention is not limited to contents of the above-described embodiment, and various modifications may be made within the scope described in the following claims. In other words, embodiments obtained by combining technical means appropriately changed within the scope indicated in the claims are also included in the technical scope of the invention.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. A non-transitory computer-readable storage medium having computer-executable instructions stored thereon, which when executed by a processor. cause the processor to perform a method comprising:
acquiring a plurality of recipe data related to a plurality of recipes, each of the plurality of recipes including processing steps executed sequentially for processing a substrate, the plurality of the recipe data including contents of each processing step and a processing result of each processing step, and
arranging graphic images representing the processing steps included in the plurality of the recipes based on the plurality of the recipe data in an order in which the processing steps are executed, and displaying display the graphic images in a tree shape such that the processing steps having common contents across the plurality of the recipes are grouped into one group and the processing steps having different contents are branched.

2. The non-transitory computer-readable storage medium according to claim 1, wherein the method further comprises:
displaying processing results of the processing steps represented by the graphic images in association with the graphic images based on the recipe data.

3. The non-transitory computer-readable storage medium according to claim 1, wherein the method further comprises:
omit displaying of a graphic image representing a processing step that satisfies a predetermined condition.

4. The non-transitory computer-readable storage medium according to claim 1, wherein
the processing result includes an experimental result or a simulation result.

5. The non-transitory computer-readable storage medium according to claim 1, wherein the method further comprises:
receiving specification of a processing step, and
highlighting a graphic image representing a processing step equivalent to the specified processing step, or graphic images representing a combination equivalent to a combination of consecutive processing steps including the specified processing step.

6. The non-transitory computer-readable storage medium according to claim 1, wherein the method further comprises:
creating a new processing step to be executed subsequent to any one of the processing steps,
executing a simulation for the new processing step, and
displaying a graphic image of the new processing step and a result of the simulation.

7. The non-transitory computer-readable storage medium according to claim 1, wherein the method further comprises;
receiving specification of processing steps represented by the graphic images in a grouped manner, and
displaying processing results of the processing steps based on the plurality of the recipe data related to the plurality of the recipes including the processing steps.

8. The non-transitory computer-readable storage medium according to claim 7, wherein the method further comprises:
displaying the processing results in a list format.

9. The non-transitory computer-readable storage medium according to claim 1, wherein the method further comprises:
adjusting a color of a graphic image representing each processing step according to contents of each processing step or a processing result of each processing step.

10. The non-transitory computer-readable storage medium according to claim 9, wherein
the recipe data includes a Loss value based on an experimental result of each processing step and a Loss value based on a simulation result of each processing step, and
the computer is further caused to divide the graphic image into two regions, adjust one of the regions according to the Loss value based on the experimental result, and adjust the other region according to the Loss value based on the simulation result.

11. An information processing method comprising:
acquiring a plurality of recipe data related to a plurality of recipes, each of the plurality of recipes including processing steps executed sequentially for processing a substrate, the recipe data including contents of each processing step and a processing result of each processing step, and
arranging graphic images representing the processing steps included in the plurality of the recipes based on the plurality of the recipe data in an order in which the processing steps are executed, and displaying the graphic images in a tree shape such that the processing steps having common contents across the plurality of the recipes are grouped into one group and the processing steps having different contents are branched.

12. An information processing device comprising:
circuitry configured to:
acquire a plurality of recipe data related to a plurality of recipes, each of the plurality of recipes including processing steps executed sequentially for processing a substrate, the recipe data including contents of each processing step and a processing result of each processing step, and
arrange graphic images representing the processing steps included in the plurality of the recipes based on the plurality of the recipe data in the order in which the processing steps are executed, and display the graphic images in a tree shape such that the processing steps having common contents across the plurality of the recipes are grouped into one group and the processing steps having different contents are branched.

13. The information processing method according to claim 11, further comprising:
receiving a user input to create a new processing step to be executed subsequent to any one of the processing steps based on the displayed graphic images in the tree shape and the processing results;
creating the new processing step;
executing a simulation for the new processing step;
displaying a simulation result of the new processing step;
receiving a selection of the new processing step based on the displayed simulation result; and
storing new recipe data including the selected new processing step in a recipe database.

14. The information processing device according to claim 12, wherein the circuitry is further configured to:
receive a user input to create a new processing step to be executed subsequent to any one of the processing steps based on the displayed graphic images in the tree shape and the processing results,
create the new processing step,
execute a simulation for the new processing step, display a simulation result of the new processing step,
receive a selection of the new processing step based on the displayed simulation result, and
store new recipe data including the selected new processing step in a recipe database.

15. The non-transitory computer-readable storage medium according to claim 1, wherein the method further comprises:
receiving a user input to create a new processing step to be executed subsequent to any one of the processing steps based on the displayed graphic images in the tree shape and the processing results;
creating the new processing step:
executing a simulation for the new processing step;
displaying a simulation result of the new processing step;
receiving a selection of the new processing step based on the displayed simulation result; and
storing new recipe data including the selected new processing step in a recipe database.

16. The information processing device according to claim 12, wherein the circuitry is further configured to:
display processing results of the processing steps represented by the graphic images in association with the graphic images based on the recipe data.

17. The information processing device according to claim 12, wherein the circuitry is further configured to:
omit display of a graphic image representing a processing step that satisfies a predetermined condition.

18. The information processing device according to claim 12, wherein:
the processing result includes an experimental result or a simulation result.

19. The information processing device according to claim 12, wherein the circuitry is further configured to:
receive specification of a processing step, and
highlight a graphic image representing a processing step equivalent to the specified processing step, or graphic images representing a combination equivalent to a combination of consecutive processing steps including the specified processing step.

20. The information processing device according to claim 12, wherein the circuitry is further configured to:
create a new processing step to be executed subsequent to any one of the processing steps,
execute a simulation for the new processing step, and
display a graphic image of the new processing step and a result of the simulation.
